(19) United States
(12) Patent Application Publication
(10) Pub. No.: US 2013/0082936 A1
(43) Pub. Date: Apr. 4, 2013

(54) SENSOR ARRAY WITH HIGH LINEARITY

(71) Applicants: Dauren ISLAMKULOV, Berkshire (GB); Sergio Garcia CASTILLO, Oxfordshire (GB); Christopher James BROWN, Oxford (GB)

(72) Inventors: Dauren ISLAMKULOV, Berkshire (GB); Sergio Garcia CASTILLO, Oxfordshire (GB); Christopher James BROWN, Oxford (GB)

(73) Assignee: SHARP KABUSHIKI KAISHA, Osaka (JP)

(21) Appl. No.: 13/248,156

(22) Filed: Sep. 29, 2011

(51) Int. Cl. G06F 3/041; H01L 27/146; G01J 1/42

(52) U.S. Cl. 345/173; 250/208.2; 250/208.1

(57) ABSTRACT

A sensor array includes a plurality of pixel sensor circuits; and a current-mode readout circuit to sample signals generated in each pixel sensor circuit; and addressing circuitry to individually select each pixel sensor circuit. Each pixel sensor circuit includes: a transducer and an amplifying element coupled to the transducer and configured to output a signal current which varies as a function of a measured physical property. The current-mode readout circuit includes: a sense signal line coupled to each of the amplifying elements in order to monitor the voltage presented across the amplifying element of the selected pixel sensor circuit; a drive signal line coupled to an output of each of the amplifying elements in order to provide a constant bias voltage to the amplifying element of the selected pixel sensor circuit; and a current conveyor circuit coupled to the sense signal line and drive signal line.

### TECHNICAL FIELD

The invention belongs in the field of large area sensor arrays. More specifically, the invention can be used to improve the performance of a class of sensor array readout circuits known as current-mode readout circuits. The invention is particularly relevant to sensor arrays with high address line resistances as occurs, for example, when the array is of a large physical size or when the process technology used in the fabrication of the array limits the conductivity of the material that can be used to create the address line.

This invention finds application in different types of sensor arrays such as, but not limited to, image sensor arrays, chemical sensor arrays and touch panels including touch panels integrated within liquid crystal display (LCD) devices.

### BACKGROUND ART

Sensor arrays are formed by a plurality of sensor pixels wherein each pixel contains a transducer to convert some physical property—such as, but not limited to, light, temperature, pressure, capacitance or the concentration of particular chemicals—to an electrical signal. A typical sensor array includes a matrix of sensor pixels in which the physical property is converted to an electrical signal and a read-out circuit to sample the signals generated in each pixel.

Sensor arrays may be classified by the type of pixel circuit used in the array. One well-known type of pixel circuit, called an active pixel sensor (APS), employs an amplifying element in each pixel to improve the signal-to-noise ratio of the sensor system and hence increase the accuracy of the measurement. A typical pixel circuit used in sensor arrays is the three-transistor active pixel sensor (3T-APS) as described, for example, in U.S. Pat. No. 5,471,515 (E. Fossum et al.; published 11 Nov. 1995) and shown in the schematic diagram of FIG. 1. The 3T-APS may consist of a single transducer 14 and three transistors: a reset transistor 13; a selection transistor 12; and an amplifier transistor 11 which acts as the aforementioned amplifying element. The transducer 14 is connected both to the gate terminal of the amplifier transistor 11 and to a low potential power supply line (VSS) 18. A reset address line (RST) 16 is connected to the gate terminal of the reset transistor 13 and a row select line (RWS) 17 is connected to the gate terminal of the selection transistor 12. An output signal line 21 connects the source terminal of the selection transistor 12 to the read-out circuit 20. When arranged in a matrix, the reset address line (RST) 16 and the row select address line (RWS) 17 are common to all pixels in one row and the output signal line 21 is common to all pixels in one column. The read-out circuit 20 may simply include a single biasing transistor 22 which forms a source follower amplifier with the pixel amplifier transistor 11. The gate terminal of the biasing transistor 22 may be connected to a constant bias voltage (VB) 23 and output voltage of the read-out circuit output terminal (V_{OUT}) 24 may be generated at the drain terminal of the biasing transistor 22.

In operation, the transducer 14 of the APS generates a voltage, V_{SEN}, which is a function of the strength of the physical signal being measured. This generated voltage is subsequently read-out from the matrix in a sampling operation by the read-out apparatus 20 such that the voltage generated at the read-out output terminal (V_{OUT}) 24 is also indicative of the strength of the physical signal measured by the pixel.

One of the drawbacks of the voltage-mode read-out circuit 20 is directly related to the fact that the output voltage, V_{OUT}, is generated on the output signal line 21 itself. This results in a high power consumption since the entire parasitic capacitance of the address line (RWS) 17 must be charged during the sampling operation. Further, during a normal operation of the sensor array, the output signal line 21 is sequentially connected to all pixels within one column. Since each pixel is likely to contain a different level of signal, the output signal line 21 must be charged or discharged to a different output voltage level for each separate sampling operation. The process of charging and discharging this source line at high frequency results in high power losses and, due to the finite resistance of the output signal line 21, also places a limit on the speed at which the sampling operation may be performed.

An alternative type of read-out circuit is known as a current mode read-out circuit. In this type of read-out circuit the output signal lines 21 of the sensor array are maintained at a constant potential during the sampling operation. Accordingly, the parasitic capacitance associated with the output signal lines 21 is not charged during the sample operation. Compared with voltage-mode type read-out circuits, the current-mode type therefore offers a reduction in power consumption and increase in the speed of operation of the sensor array.

One of the simplest current-mode read-out circuit architectures is disclosed in U.S. Pat. No. 7,782,383 (A. Olsen et al.: published 24 Aug. 2010) and shown in FIG. 2. The read-out circuit 20a consists of a current integrator circuit including an operational amplifier 30, an integrating capacitor 31 and a reset switch 32 that may be realised by a transistor. The operational amplifier 30 is arranged with its negative input connected to the output signal line 21 and its positive input connected to a constant reference voltage (VB) 33. The integrating capacitor 31 is connected between the output signal line 21 and the output of the operational amplifier 30 and the reset switch 32 is connected in parallel to the integrating capacitor 31.

In operation, when a pixel circuit is being sampled by the read-out circuit 20a, the signal line current (I_{PIX}) in the output signal line 21 flows into the resultant integrator circuit, which converts it into voltage, according to the following equation:

$${V}_{OUT} = {V}_{B 2} - \frac{{I}_{PIX} Δ t}{{C}_{INT}}$$

where Δt is the integrating period and C_{INT} is the capacitance of the integrating capacitor 31. As a result, in theory, the integrator's output voltage, V_{OUT}, at the read-out output terminal 24 is linearly proportional to the strength of the signal being measured by the transducer 14.

A disadvantage of using a single operational amplifier 30 to both bias the signal line 21 and perform current integration however is the high bandwidth requirement of the operational amplifier 30. In practice, a non-ideal operational amplifier does not exhibit infinite bandwidth and may therefore be unable to sustain accurate voltage at its negative input terminal during the periods when the output voltage of the operational amplifier 30 changes quickly. As a result, during the signal integration period, the amplifier transistor 11 (FIG. 1) will exhibit a non-linear response and the accuracy of the sensor system is reduced. Whilst it is possible to provide an operational amplifier with sufficiently high bandwidth, such amplifiers typically exhibit high power consumption and require expensive, non-standard processing techniques to manufacture.

An example of an alternative current-mode read-out circuit 20b is disclosed in, for example, US20080291309 (V. Gruev et al.; published 27 Nov. 2008) and shown in FIG. 3. This type of read-out architecture consists of two stages. The first stage employs what is known as a current conveyor circuit 40, while the second stage consists of a current integrator circuit 50 similar to that described previously with respect to the read-out circuit 20a.

The current conveyor circuit 40 includes an input transistor 44 and an output transistor 45 which together form a current mirror, and an operational amplifier 42. The source terminals of the input transistor 44 and the output transistor 45 are connected to a low voltage power supply, such as the system ground potential, while their gate terminals are connected together and to the output of the operational amplifier 42. The drain terminal of the input transistor 44 is connected to the positive input of the operational amplifier 42. The drain terminal of the input transistor 44 also acts as an input terminal of the current conveyor circuit 40. The drain terminal of the output transistor 45 acts as an output terminal of the current conveyor circuit 40. The negative output of the operational amplifier 42 is connected to a constant reference voltage (VB2) 34.

The current conveyor circuit 40 maintains the output signal line 21 at a constant voltage and therefore provides a constant bias voltage for the pixel amplifier transistor 11 (FIG. 1). The current conveyor circuit 40 is also arranged to receive the drain current, I_{PIX}, of the sensor's amplifier transistor 11 on the output signal line 21 which is copied to the current conveyor output terminal 43 and input to the current integrator 50 at input node V_{N} by the current mirror formed by the input transistor 44 and the output transistor 45. The current integrator circuit 50 includes an operational amplifier 53 to which the negative input terminal is connected to the input node V_{N} and the positive input terminal is connected to constant reference voltage (VB3) 35. The current integrator circuit 50 converts the output current from the current conveyor circuit 40 into an output voltage (V_{OUT}) on read-out circuit output terminal 36.

In the two-stage current-mode read-out architecture of FIG. 3 the main two functions of the readout system—biasing of the pixel amplifier transistor 11 and current-to-voltage (I-V) conversion—are split between two stages. As a result, the operational amplifier 53 within the current integrator circuit 50 does not need to maintain a constant voltage at its input, and therefore its gain-bandwidth requirement is much lower than the operational amplifier of a single-stage current-mode readout system. Meanwhile, the operational amplifier 42 of the current conveyor circuit 40 does need to maintain a constant bias voltage at its input but, since the operational amplifier 42 does not drive a high capacitive load, the performance requirements for this operational amplifier are also low.

A disadvantage common to known current-mode type read-out circuits however is that in practice they exhibit lower input-to-output linearity than voltage-mode type read-out circuits. The main source of non-linearity in current-mode read-out circuits is caused by the finite resistance of the pixel select transistor 12 and the parasitic intrinsic resistance of the output signal line 21, i.e. the combined series resistance of all circuit elements that connect the APS 10 to the readout circuit 20a, 20b. These parasitic resistances may be especially significant in physically large area sensor arrays containing long address lines or when the sensor array is fabricated with high resistivity or low channel mobility process technologies, such as low-temperature poly-silicon or amorphous silicon processes common in the manufacture of LCDs. This parasitic resistance will generate a voltage drop between the pixel sensor and read-out circuit dependent on both the value of the signal current, I_{PIX}, and the total resistance existing between the pixel sensor and the read-out circuit. As a result, the effective drain-source bias voltage across the pixel amplifier transistor 11 (FIG. 1) in the APS 10 may be approximated by the following equation:

VB_{EFF}=VB−I_{PIX}×R_{PAR}

where, VB_{EFF} is the effective drain-source voltage seen by the amplifier transistor 11 of the sensor; VB is the desired drain-source voltage seen by the amplifier transistor 11 set by the readout circuit; I_{PIX} is the drain current of the amplifier transistor 11 which corresponds to the strength of the signal being measured; R_{PAR} is the total parasitic resistance of all the components connecting the amplifier transistor 11 of the sensor with the corresponding read-out circuit 20a, 20b.

As evident from the above equation, during the pixel sampling operation the amplifier transistor 11 will operate with a voltage between its drain and source terminals that varies depending on the strength of the signal being measured. As a result, the current-mode read-out circuit will exhibit non-linear response as exemplified in FIG. 4 and the accuracy of the sensor system will be reduced.

### SUMMARY OF THE INVENTION

This invention provides a means of reading out signals from active pixel sensor arrays using a current-mode type readout method while overcoming the problem of non-linear response that is common to known current-mode read-out systems.

In this invention the non-linearity is suppressed based on a novel current-mode readout circuit and a novel configuration of the signal lines of the sensor array. The novel read-out circuit and signal line configuration are arranged to incorporate the parasitic resistance of the signal lines inside the feedback loop of the current conveyor circuit. This arrangement allows for a more stable bias voltage to be maintained across the pixel amplifier transistor. As a result, the read-out circuit has a reduced dependency on the parasitic resistance of the signal address lines and the system provides a more accurate measurement of the physical property being measured by the array.

According to an aspect of the invention, a sensor array is provided which includes a plurality of pixel sensor circuits; a current-mode readout circuit to sample signals generated in each pixel sensor circuit; and addressing circuitry to individually select each pixel sensor circuit. Each pixel sensor circuit includes: a transducer which converts a physical property to be measured to an electrical signal; and an amplifying element coupled to the transducer and configured to output a signal current which varies as a function of the measured physical property; and the current-mode readout circuit includes: a sense signal line coupled to each of the amplifying elements in order to monitor the voltage presented across the amplifying element of the selected pixel sensor circuit; a drive signal line coupled to an output of each of the amplifying elements in order to provide a constant bias voltage to the amplifying element of the selected pixel sensor circuit; and a current conveyor circuit coupled to the sense signal line and drive signal line and configured to monitor the voltage presented across the amplifying element of the selected pixel sensor circuit using the sense signal line, provide the constant bias voltage to the amplifying element of the selected pixel sensor circuit using the drive signal line, and produce an output which is a function of the output signal current of the amplifying element of the selected pixel sensor circuit.

According to another aspect, each pixel sensor circuit includes an amplifier transistor as the amplifying element, the amplifier transistor having an input terminal coupled to an output of the transducer, a first output terminal coupled to a pixel reference voltage address line, and a second output terminal coupled to the sense signal line and the drive signal line.

According to another aspect, each pixel sensor circuit includes a select transistor having a first output terminal and a second output terminal through which the second output terminal of the amplifier transistor is coupled to the drive signal line, and the addressing circuitry includes a row select addressing line coupled to an input terminal of the select transistor for selecting the pixel sensor circuit.

In accordance with still another aspect, each pixel sensor circuit includes a reset transistor coupled to a reset address line included in the addressing circuitry for resetting an output of the transducer.

According to another aspect, the current conveyor circuit includes an operational amplifier, input transistor and output transistor arranged in a current mirror, the input transistor being coupled to the drive signal line to receive the output signal current of the amplifying element of the selected pixel sensor circuit, the output transistor being coupled to the output of the current conveyor circuit, input terminals of the operational amplifier being coupled to the sense signal line and a current conveyor reference voltage, respectively, and an output terminal of the operational amplifier being coupled to input terminals of the input transistor and output transistor.

In accordance with another aspect, a first output terminal, second output terminal and the input terminal of the input transistor are coupled to the drive signal line, a low potential power supply line, and the output of the operational amplifier, respectively; a first output terminal, second output terminal and the input terminal of the output transistor are coupled to the output of the current conveyor circuit, the low potential power supply line, and the output of the operational amplifier, respectively; and a positive terminal and a negative terminal of the operational amplifier are coupled to the sense signal line and the current reference voltage, respectively.

In accordance with still another aspect, a first output terminal, second output terminal and the input terminal of the input transistor are coupled to the drive signal line, a high potential power supply line, and the output of the operational amplifier, respectively; a first output terminal, second output terminal and the input terminal of the output transistor are coupled to the output of the current conveyor circuit, the high potential power supply line, and the output of the operational amplifier, respectively; and a negative terminal and a positive terminal of the operational amplifier are coupled to the sense signal line and the current reference voltage, respectively.

According to still another aspect, the current conveyor circuit including an operational amplifier, and an input bias branch and an output bias branch, wherein each of the input bias branch and the output bias branch includes an upper part and a lower part; the upper part of the input bias branch and the upper part of the output bias branch are arranged to form a first current mirror, while the lower part of the input bias branch and the lower part of the output bias branch are arranged to form a second current mirror; the drive signal line is connected to a node connecting the upper and lower parts of the input bias branch; the sense signal line is connected to a negative input terminal of the operational amplifier; a current conveyor reference voltage is connected to a positive input terminal of the operational amplifier; and an output of the current conveyor circuit is connected to a node connecting the upper and lower parts of the output bias branch.

In accordance with still another aspect, the current-mode readout circuit includes a current integrator circuit which integrates the output of the current conveyor circuit to produce an output voltage which is a function of the output signal current of the amplifying element of the selected pixel sensor circuit.

According to another aspect, the input bias branch includes a first p-type transistor and first and second n-type transistors connected in series between high and low potential power supplies; the output bias branch includes a second p-type transistor and third and fourth two n-type transistors connected in series between the high and low potential power supplies, the first and second p-type transistors are matched to form the first current mirror; one of the first and second n-type transistors of the input bias branch and one of the third and fourth n-type transistors of the output bias branch are matched to form the second current mirror; the output terminal of the operational amplifier is connected to gate terminals of the other of the first and second n-type transistors of the input bias branch and the other of the third and fourth n-type transistors of the output bias branch; the node the drive signal line is connected to is a node connecting the first and second n-type transistors of the input bias branch; and the node the output of the current conveyor circuit is connected to is a node connecting the third and fourth n-type transistors of the output bias branch.

According to yet another aspect, the current-mode readout circuit includes a current integrator circuit for integrating the output of the current conveyor circuit, the current integrator circuit including a third p-type transistor and a fifth n-type transistor connected in series between the high and low power supplies, connected to form an amplifying stage therewith; an integration capacitor connected between a node between the third and fourth n-type transistors of the output bias branch and a node between the third p-type transistor and the fifth n-type transistor; and a voltage at the node between the third p-type transistor and the fifth n-type transistor represents an output voltage which is a function of the output signal current of the amplifying element of the selected pixel sensor circuit.

In yet another aspect, each pixel sensor circuit includes an amplifier transistor as the amplifying element, the amplifier transistor having an input terminal coupled to an output of the transducer, a first output terminal, and a second output terminal which is coupled to the sense signal line and the drive signal line; and the current-mode readout circuit further includes: another sense signal line coupled to the first output terminal of each of the amplifier transistors in order to monitor the voltage presented across the amplifying element of the selected pixel sensor circuit; and another drive signal line coupled to the first output terminal of each of the amplifier transistors in order to provide a constant bias voltage to the first output terminal of the amplifier transistor of the selected pixel sensor circuit.

According to still another aspect, each pixel sensor circuit includes a first switch transistor having a first output terminal and a second output terminal through which the second output terminal of the amplifier transistor is coupled to the drive signal line, a second switch transistor having a first output terminal and a second output terminal through which the first output terminal of the amplifier transistor is coupled to the another drive signal line, and the addressing circuitry includes a row select addressing line coupled to a input terminal of the first and second switch transistors for selecting the pixel sensor circuit.

In accordance with another aspect, the current-mode readout circuit includes a biasing circuit including an operational amplifier having a reference voltage connected to a positive input terminal thereof, and an output terminal of the operational amplifier being coupled to a negative input terminal thereof via the another drive signal line, the second switch transistor and the another sense signal line.

According to another aspect, the current conveyor circuit includes a first operational amplifier, first input transistor and first output transistor arranged in a first current mirror, the first input transistor being coupled to the drive signal line to receive the output signal current of the amplifier transistor of the selected pixel sensor circuit, and the first output transistor being coupled to a first input of a differential current integrator circuit; and further including another current conveyor circuit including a second operational amplifier, second input transistor and second output transistor arranged in a second current mirror, the second input transistor being coupled to the another drive signal to source current to the amplifier transistor of the selected pixel sensor circuit, and the second output transistor being coupled to a second input of the differential current integrator circuit, wherein one input terminal of the first and second operational amplifiers is coupled to the sense signal line and another sense signal line, respectively; and another input terminal of the first and second operational amplifiers is coupled to first and second current conveyor reference voltages, respectively.

According to another aspect, a matrix-type sensor array includes a plurality of sensor arrays, wherein the plurality of pixel sensor circuits of each of the plurality of sensor arrays are arranged to form a corresponding column in a matrix of rows and columns.

In accordance with still another aspect, multiple ones of the plurality of sensor arrays share a same current conveyor circuit selectively coupled to the corresponding sense signal line and drive signal line via a multiplexer.

According to yet another aspect, a touch display includes a plurality of display pixels for providing a display, and a matrix-type sensor array as described herein.

According to yet another aspect, column addressing lines within the matrix-type sensor array are configured to serve a dual purpose of supplying display data to display pixels in the display and to sample the output of active pixel sensor circuits within the sensor array.

In another aspect, each pixel sensor circuit is common to multiple ones of the display pixels.

According to another aspect, an image sensor array, chemical sensor array or touch panel as described herein.

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

In the annexed drawings, like references indicate like parts or features:

FIG. 1 shows a typical conventional voltage-mode read-out method for sensor arrays;

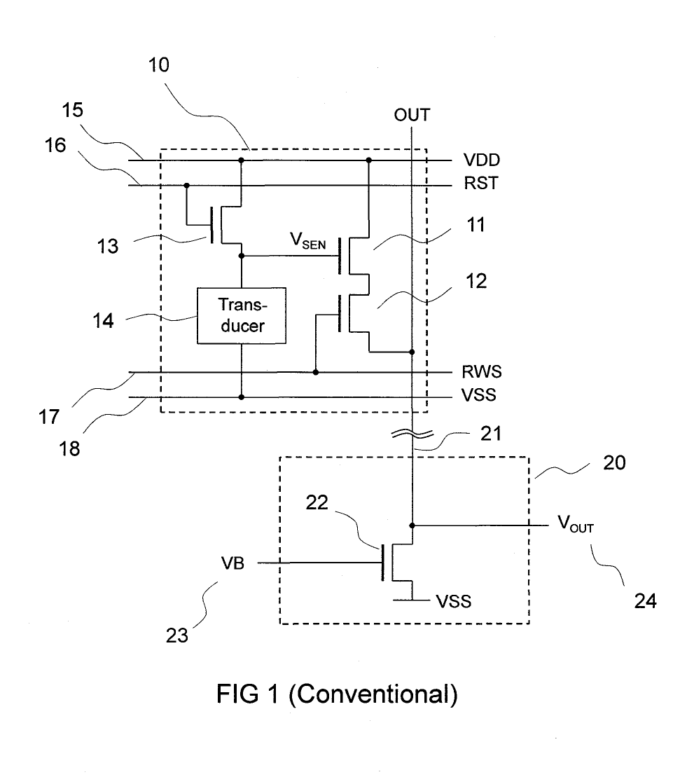

FIG. 2 shows an example of a simple current-mode readout method using a simple conventional current integrator circuit;

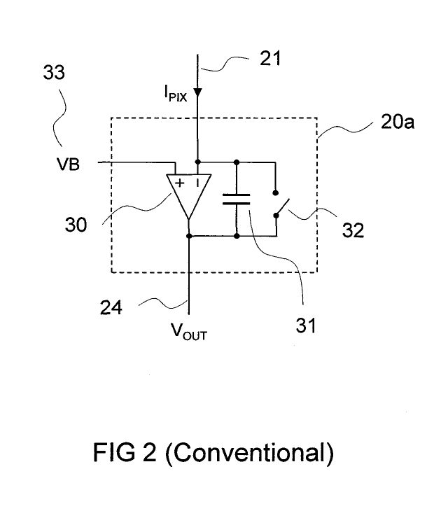

FIG. 3 shows an example of a read-out method using a conventional current conveyor circuit;

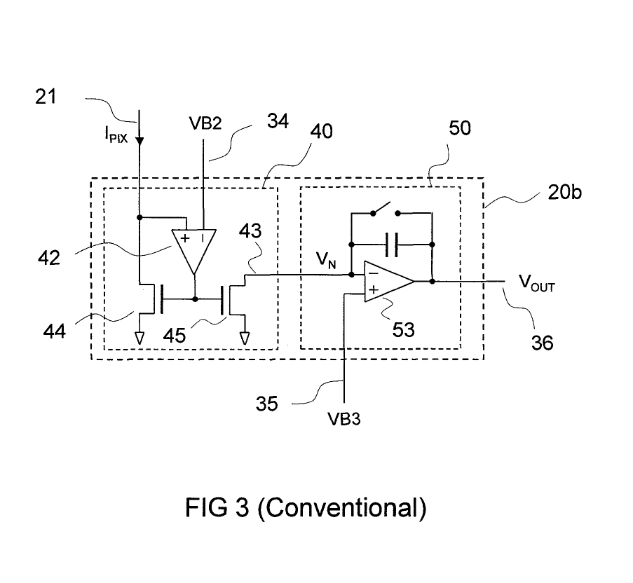

FIG. 4 shows a graph illustrating the effect of parasitic resistance in the addressing line between the pixel and read-out circuits;

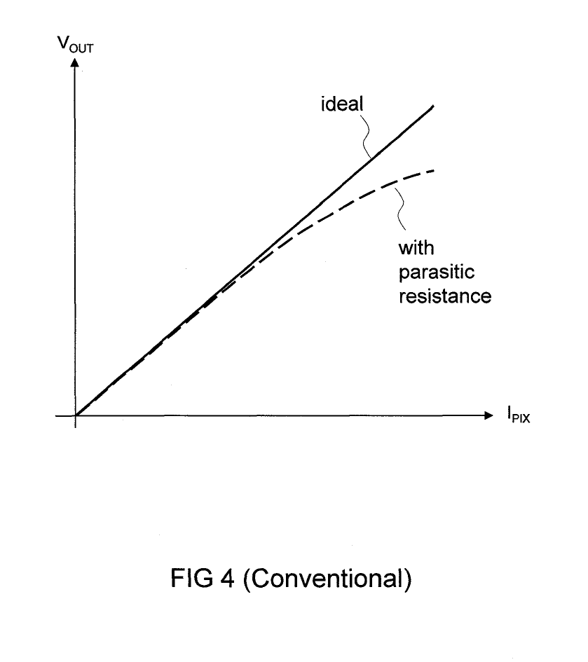

FIG. 5 shows a schematic diagram of a first and most basic embodiment of the invention;

FIG. 6 shows a waveform diagram illustrating the operation of the first and most basic embodiment of the invention;

FIG. 7 shows a block diagram of a sensor array incorporating the first and most basic embodiment of the invention;

FIG. 8 shows a schematic diagram of a pixel circuit in accordance with a second embodiment of this invention;

FIG. 9 shows a schematic diagram of a current conveyor circuit in accordance with a third embodiment of this invention;

FIG. 10 shows a schematic diagram of a current conveyor circuit in accordance with a fourth embodiment of this invention;

FIG. 11 shows a schematic diagram of a read-out circuit in accordance with a fifth embodiment of this invention;

FIG. 12 shows a schematic diagram of a pixel circuit and read-out circuit in accordance with a sixth embodiment of this invention;

FIG. 13 shows a schematic diagram of a pixel circuit in accordance with a seventh embodiment of this invention;

FIG. 14 shows a block diagram in accordance with an eighth embodiment of this invention;

FIG. 15 shows a system block diagram in accordance with a ninth embodiment of this invention;

FIG. 16 shows a schematic diagram of a pixel circuit in accordance with a ninth embodiment of this invention; and

FIG. 17 shows a waveform diagram illustrating the operation a ninth embodiment of this invention.

### DESCRIPTION OF REFERENCE NUMERALS

10—conventional active pixel sensor circuit

11—amplifier transistor

12—selection transistor

13—reset transistor

14—transducer

15—positive power supply rail

16—reset addressing line

17—row select line

18—negative power supply rail

20—read-out circuit

21—output signal line

22—column bias transistor

23—reference voltage signal

24—read-out circuit output terminal

30—operational amplifier

31—integrating capacitor

32—integrator reset switch

33—integrator reference voltage terminal

34—integrator reference voltage terminal

36—read-out circuit output terminal

40—current conveyor circuit

42—operational amplifier

43—current conveyor output terminal

44—current conveyor input transistor

45—current conveyor output transistor

50—current integrator circuit

53—operational amplifier

100—sensor array

110—active pixel sensor circuit

111—amplifier transistor

112—select transistor

113—reset transistor

114—transducer

115—reference voltage address line

116—reset addressing line

117—row select line

118—low potential power supply for pixel sensor circuit

131—source drive addressing line (drive signal line)

132—source sense addressing line (sense signal line)

134—current conveyor reference voltage

135—integrator reference voltage

136—read-out circuit output terminal

200—read-out circuit

210—current conveyor circuit

212—operational amplifier

213—current conveyor output terminal

214—current conveyor input transistor

215—current conveyor output transistor

216—low potential power supply for current conveyor

220—current integrator circuit

221—integrator reset switch

222—operational amplifier

223—integrating capacitor

224—integrator reset signal

240—control apparatus

241—read-out apparatus

242—multiplexer

243—analog-to-digital convertor

300—active pixel sensor circuit of second embodiment

301—amplifier transistor

302—source switch transistor

303—select capacitor

304—photodiode

311—reference voltage address line

312—row select address line

313—additional select address line

314—reset address line

340—current conveyor circuit of third embodiment

341—operational amplifier

342—current conveyor input transistor

343—current conveyor output transistor

360—current conveyor circuit of fourth embodiment

361—operational amplifier

362—input bias branch of current conveyor circuit

363—output bias branch of current conveyor circuit

370—p-type transistor

371—n-type transistor

372—n-type transistor

373—bias voltage

374—bias voltage

375—p-type transistor

376—n-type transistor

377—n-type transistor

378—bias voltage

380—current integrator circuit of fifth embodiment

381—p-type transistor

382—n-type transistor

383—integrator reset switch transistor

384—integrating capacitor

400—read-out circuit of sixth embodiment

410—pixel circuit of sixth embodiment

411—amplifier transistor

412—source switch transistor

413—drain switch transistor

414—reset transistor

415—transducer

416—reset address line

417—row select address line

418—low potential power supply

421—drain drive addressing line

422—drain sense addressing line

430—biasing circuit

431—operational amplifier

432—drain reference voltage signal

500—read-out circuit of seventh embodiment

510—first current conveyor circuit

511—operational amplifier

512—current conveyor input transistor

513—current conveyor output transistor

515—negative input terminal of differential current integrator circuit

520—second current conveyor circuit

521—operational amplifier

522—current conveyor input transistor

523—current conveyor output transistor

525—positive input terminal of differential current integrator circuit

530—differential current integrator circuit

531—operational amplifier

532—first integrating capacitor

533—second integrating capacitor

600—read-out apparatus of eighth embodiment

610—first multiplexer

611—source drive signal

612—source sense signal

620—second multiplexer

700—display substrate

701—display controller

702—sensor controller

710—pixel matrix

711—pixel

712—active pixel sensor circuit elements

713—display circuit elements

720—read-out circuit

721—multiplexer

722—analog-to-digital convertor

723—processing unit

730—switch transistor

731—liquid crystal element

732—storage capacitor

733—gate addressing line

734—storage capacitor addressing line

735—first column addressing line

736—second column addressing line

737—third column addressing line

740—select capacitor

741—photodiode

742—amplifier transistor

743—source switch transistor

744—row select address line

745—reset address line

### DETAILED DESCRIPTION OF INVENTION

This invention provides means of reading-out signals from active pixel sensor arrays using a current-mode readout method, while providing a highly-linear input-output response of the sensor system. The invention includes a novel current-mode readout circuit and a novel configuration of the signal address lines of the sensor array which are arranged together to reduce the system's dependency on any parasitic resistance that may exist between the sensor pixels and the readout circuit.

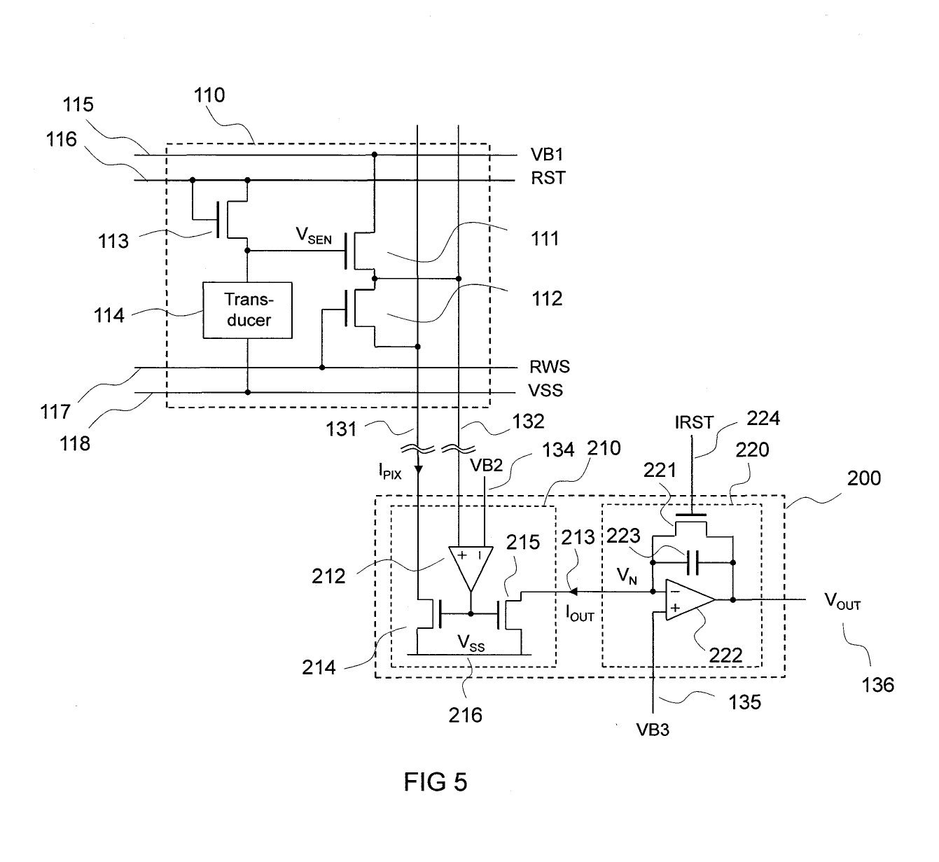

A schematic diagram of an array element circuit according to the first and most basic embodiment of this invention is shown in FIG. 5 and includes an active pixel sensor circuit 110 and a read-out circuit 200. The active pixel sensor circuit 110 may be of a known type such as a three transistor active pixel sensor circuit (3T-APS) and consist, for example, of a transducer 114 and three transistors: an amplifier transistor 111; reset transistor 113; and a selection transistor 112. The transducer 114 is connected both to the gate terminal of the amplifier transistor 111 and to a low potential power supply line (VSS) 118. A reset address line (RST) 116 is connected to the gate and drain terminals of the reset transistor 113, a row select line (RWS) 117 is connected to the gate terminal of the selection transistor 112 and a reference voltage address line (VB1) 115 is connected to the drain terminal of the amplifier transistor 111. The source terminal of the selection transistor 112 is connected to the read-out circuit 200 by means of a source drive addressing line 131 and the source terminal of the amplifier transistor 111 is connected to the readout circuit 200 by means of source sense addressing line 132. The read-out circuit 200 of this embodiment includes a current conveyor circuit 210 and current integrator circuit 220.

The current conveyor circuit 210 further includes an operational amplifier 212 and an input transistor 214 and output transistor 215 arranged to form a current mirror. The drain terminal of the input transistor 214 is connected to the source drive addressing line 131 and the positive input terminal of the operational amplifier 212 is connected to the source sense addressing line 132. The negative input terminal of the operational amplifier 212 is connected to a current conveyor reference voltage (VB2) 134. The output terminal of the operational amplifier 212 is connected to the gate of each of the transistors 214, 215. The source terminals of each of the transistors 214, 215 are connected to the low potential power supply (V_{SS}) 216 for current conveyor circuit 210. The source sense addressing line 132 may be referred to as a ‘sense’ signal line since it is used to monitor the voltage at the source terminal of the amplifier transistor 111. The source drive addressing line 131 may be referred to as a ‘drive’ signal line since it is used to control the voltage of the source terminal of the amplifier transistor 111.

The current integrator circuit 220 may be of a well-known type and may include, for example, of an operational amplifier 222 arranged in an integrating configuration with an integrating capacitor 223 and a reset switch 221 connected between the output and negative terminals of the operational amplifier 222 in parallel with the integrating capacitor 223. The positive terminal of the operational amplifier 222 may be connected to a constant bias voltage (VB3) 135 which acts to set the voltage at the input node V_{N} of the integrator circuit.

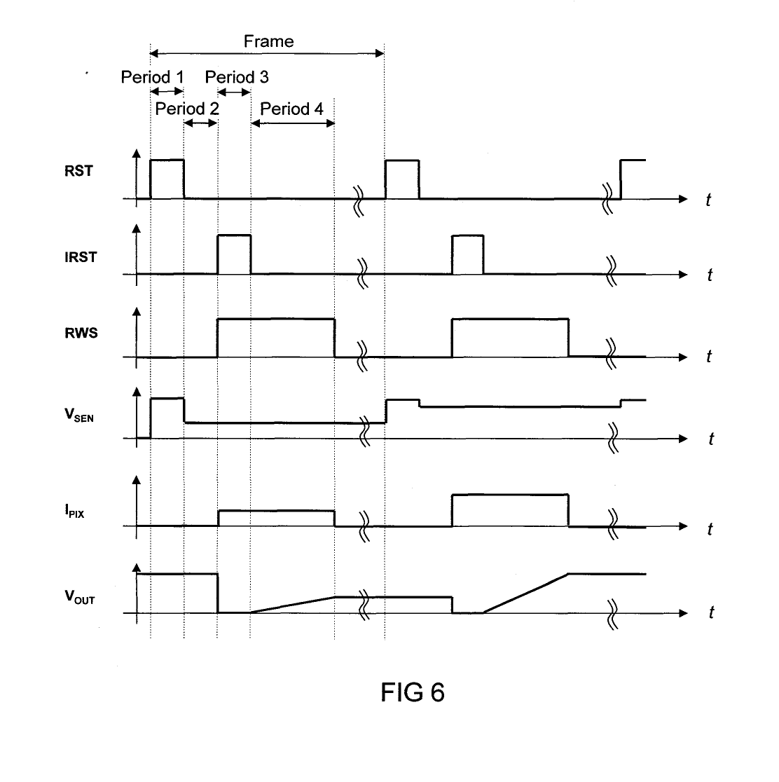

The operation cycle of the pixel sensor circuit 110 and the read-out circuit 200 are now described with reference to the schematic diagram of FIG. 5 and the waveform diagram of FIG. 6. In a first stage of operation, Period 1, the pixel sensor circuit 110 is reset by applying a pulse to the reset addressing line (RST) 116. In a second stage of operation, Period 2, which begins immediately after Period 1, the transducer 114 converts the physical signal to be measured into a voltage signal at the pixel sensing node, V_{SEN}.

During a third stage of operation, Period 3, the read-out circuit 200 is initialized prior to sampling the pixel output signal at the pixel sensing node, V_{SEN}. In this stage, the pixel row select addressing line (RWS) 117 is brought to a high potential and the pixel selection transistor 112 is turned on. Since a conductive path is now formed between the pixel reference voltage address line (VB1) 115 and the low potential power supply, V_{SS}, (via the pixel amplifier transistor 111, pixel selection transistor 112 and current conveyor input transistor 214) a signal current, I_{PIX}, now flows along the source drive addressing line 131. The signal current, I_{PIX}, is approximated by the following equation:

$$\begin{matrix}{I}_{PIX} = β [ ( {V}_{GS} - {V}_{th} ) {V}_{DS} - \frac{{V}_{DS}}{2} ] \\ = β [ ( {V}_{G} - {V}_{S} - {V}_{th} ) ( {V}_{D} - {V}_{S} ) - \frac{{( {V}_{D} - {V}_{S} )}^{2}}{2} ] \\ = β [ ( {V}_{SEN} - VB 2 - {V}_{th} ) ( VB 1 - VB 2 ) - \frac{{( VB 1 - VB 2 )}^{2}}{2} ]\end{matrix}$$

where β is a characteristic parameter of the amplifier transistor 111 that is assumed to be constant; V_{G} is the voltage at the gate of the amplifier transistor 111 (=V_{SEN}), V_{S} is the voltage at the source of the amplifier transistor 111 (=VB2); and V_{D} is the voltage at the drain of the amplifier transistor 111 (=VB1).

Since the source sense addressing line 132 is connected to the high-impedance positive input of the operational amplifier 212, no significant current flows down this path. Consequently, despite the parasitic resistance of the source sense addressing line 132, there is no voltage drop between the source terminal of the pixel amplifier transistor 111 and the positive input terminal of the operational amplifier 212. The voltage at the output terminal of the operational amplifier 212 therefore assumes a voltage which drives the input transistor 214 to maintain the source terminal of the amplifier transistor 111 at the same voltage as the current conveyor reference voltage (VB2) 134 provided at the negative input terminal of the operational amplifier 212.

During the third stage of operation, Period 3, the integrator reset signal (IRST) 224 is brought to a high potential causing the reset switch transistor 221 to turn on. The output of the operational amplifier 222 is therefore connected to its negative input terminal causing the integration capacitor 223 to discharge and maintaining the output voltage of the read-out circuit (V_{OUT}) 136 at the voltage of the reference signal (VB3) 135 provided at the positive input terminal of the operational amplifier 222.

In a fourth stage of operation, integrating Period 4, which begins immediately after Period 3, the integrator reset signal (IRST) 224 is brought low again. The current mirror formed by the input transistor 214 and output transistor 215 acts to copy the signal current, I_{PIX}, to the input of the current integrator circuit 220. The current drawn from the current integrator circuit 220, I_{OUT}, during Period 4 may be the same as the signal current, I_{PIX}, or a multiple of it depending on the ratio of the transconductances of the transistors 214, 215. The current integrator circuit 220, converts the current l_{OUT} into the output voltage (V_{OUT}) 136 of the read-out circuit 200 according to the following equation:

$${V}_{OUT} = {V}_{B 2} + \frac{{I}_{OUT} Δ t}{{C}_{INT}}$$

where V_{B2} is the current conveyor reference voltage (VB2) 134; Δt is the integrating period (Period 4); and C_{INT} is the capacitance of the integrating capacitor 223.

At the end of the fourth stage of operation the pixel row addressing line (RWS) 117 is brought low and the pixel selection transistor 112 is turned off. Accordingly, no signal current, I_{PIX}, flows into the read-out circuit 200 via the source drive addressing line 131 and the output voltage (V_{OUT}) 136 of the current integrator circuit 220 becomes constant. Thus, the output voltage (V_{OUT}) 136 of the read-out circuit 200 as a whole may now be stored or further processed, for example by conversion to a digital signal. The first to fourth stages of operation described above form one cycle or “frame” of operation which may be repeated indefinitely to generate a continual sequence of measurements.

As evident from the above description of operation, the signal current, I_{PIX}, is independent of the resistance of the addressing lines 131, 132 and the relationship between the signal current, I_{PIX}, and the voltage signal generated by the pixel circuit transducer 114, V_{SEN}, is linear. Since the output of the current integrator circuit 220 is also linearly proportional to the signal current, I_{PIX}, the output voltage of the read-out circuit 200, V_{OUT}, is linearly proportional to the strength of the signal being measured by the transducer 114. Advantageously, the accuracy of the measurements provided by the active pixel sensor are therefore improved over the prior art.

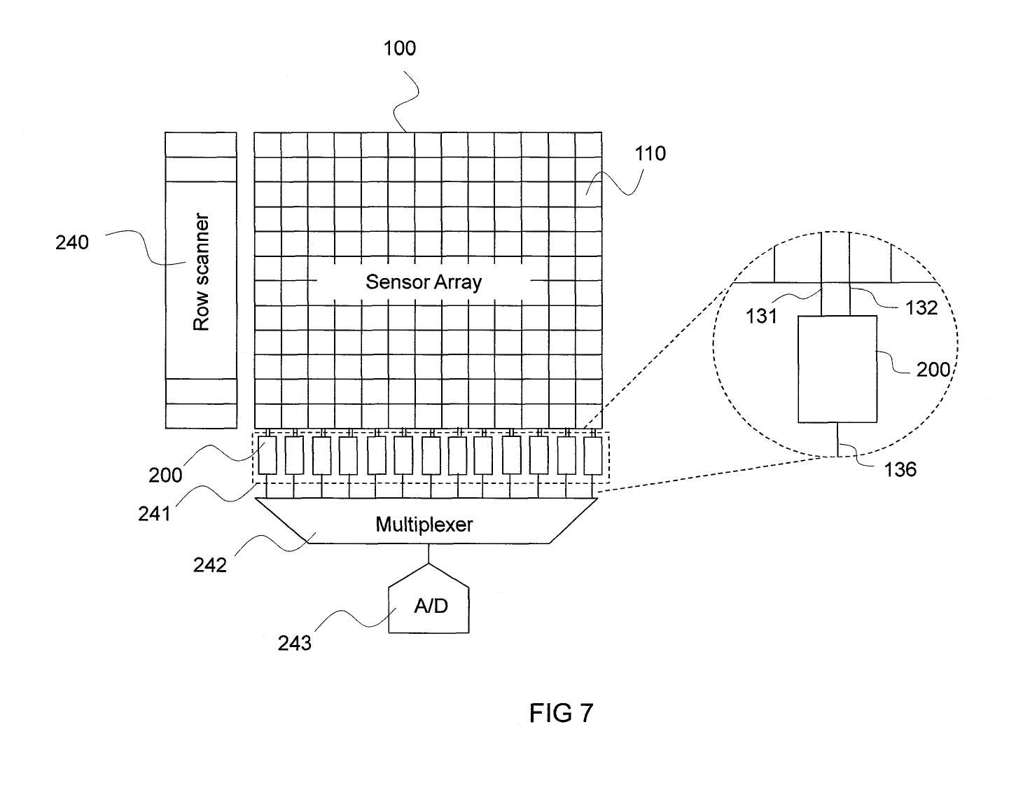

An example of a sensor array system that includes the read-out circuit 200 described above is shown in FIG. 7. The system comprises an array 100 of active pixel sensor circuits 110 arranged in a matrix of rows and columns. A control apparatus 240 and a read-out apparatus 241 are provided at the matrix periphery and are configured to control the operation of the array 100 and sample the signals generated in each pixel respectively as described herein. The read-out apparatus 241 further includes a plurality of read-out circuits 200 of a type described above with respect to FIG. 5 wherein a single column of active pixel sensor circuits 110 is connected to one individual read-out circuit 200. The control apparatus 240 generates the pixel reset (RST) and row select (RWS) signals on lines 116, 117, respectively, that control the operation of the active pixel sensor circuits 110 such that in one row of operation, all of the active pixel sensor circuits 110 in one row of the array 100 are connected to the corresponding read-out circuits 200 and sampled. After one row of active pixel sensor circuits 110 within the array 100 has been sampled, the output voltage signals, V_{OUT}, generated by the read-out circuits 200 at the corresponding read-out circuit output terminals 136 may be converted to digital signals for further processing. In a well-known arrangement, the read-out circuits 200 of the read-out apparatus 241 may therefore be connected to an analog-to-digital convertor circuit 243 via a multiplexer circuit 242. During one frame of operation, each row of pixels is addressed in turn and a digital representation of the strength of the physical signal being measured in each pixel of the array is therefore generated.

In a second embodiment of this invention, the read-out method of the first embodiment may be used in conjunction with a type of pixel circuit known as a one-transistor active pixel sensor (1T-APS), as described in for example

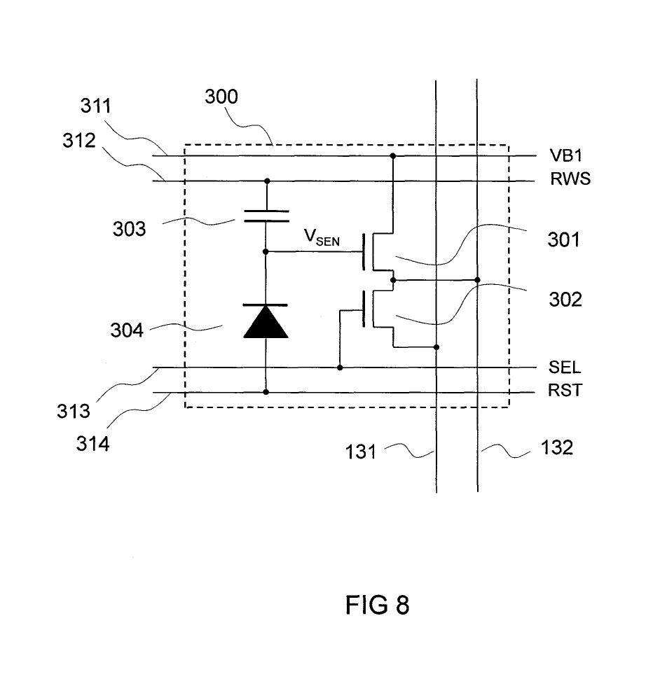

US2010/231562 (Brown, published 16 Sep. 2010). FIG. 8 shows the schematic diagram of an example of an active pixel sensor circuit 300 according to this embodiment which may be used to form an image sensor array. The active pixel sensor circuit 300 according to this embodiment includes a photodiode 304; an amplifier transistor 301; a selection transistor 302; and a selection capacitor 303. The anode terminal of the photodiode 304 is connected to a reset address line (RST) 314 and the cathode terminal to both the gate terminal of the amplifier transistor 301 and a first terminal of the selection capacitor 303. A second terminal of the selection capacitor 303 is connected to a row select line (RWS) 312 and the drain terminal of the amplifier transistor 301 is connected to a reference voltage address line (VB1) 311. An additional select addressing line (SEL) 313 is connected to the gate terminal of the selection transistor 302. The source terminal of the selection transistor 302 is connected to the read-out circuit 200 of the type in FIG. 5, for example, by means of the source drive addressing line 131 and the source terminal of the amplifier transistor 301 is connected to the readout circuit 200 by means of the source sense addressing line 132.

The operation cycle of a one-transistor active pixel sensor circuit 300 is well-known and is now described only in summary. In a manner similar to the operation of the active pixel sensor circuit 110 of the first embodiment, during the first and second stage of the operation cycle (Periods 1 and 2) the active pixel sensor circuit 110 is reset and the physical signal to be measured is converted into a voltage signal, V_{SEN}. Then, in the third and fourth stage of operation (Periods 3 and 4), the voltage signal generated in the pixel is sampled by the read-out circuit 200. The additional select addressing line (SEL) 313, provided by the control apparatus 240, may share similar timing with the row select line (RWS) 312 such that during Periods 3 and 4 the selection transistor 302 is turned on and a conductive path is formed between the reference voltage address line (VB1) 311 and the low potential power supply in the read-out circuit 200 (via the pixel amplifier transistor 301, pixel selection transistor 302 and current conveyor input transistor 214). As a result, the signal current, I_{PIX}, flows along the source drive addressing line 131.

In an alternative arrangement of the pixel circuit of this embodiment which offers a reduced circuit size and pixel fill factor, the additional select line (SEL) 313 may be removed and the row select line (RWS) 312 connected to the gate terminal of the selection transistor 302 instead. However, an advantage of the additional select line (SEL) 313 is that the high and low potentials of the row select line (RWS) 312 may be set independently and the select capacitor 303 may therefore be formed by a variable capacitor and used to increase the pixel sensitivity. Such an arrangement of variable capacitor is disclosed in WO2010/100958 (Brown et al., 7 Jan. 2010).

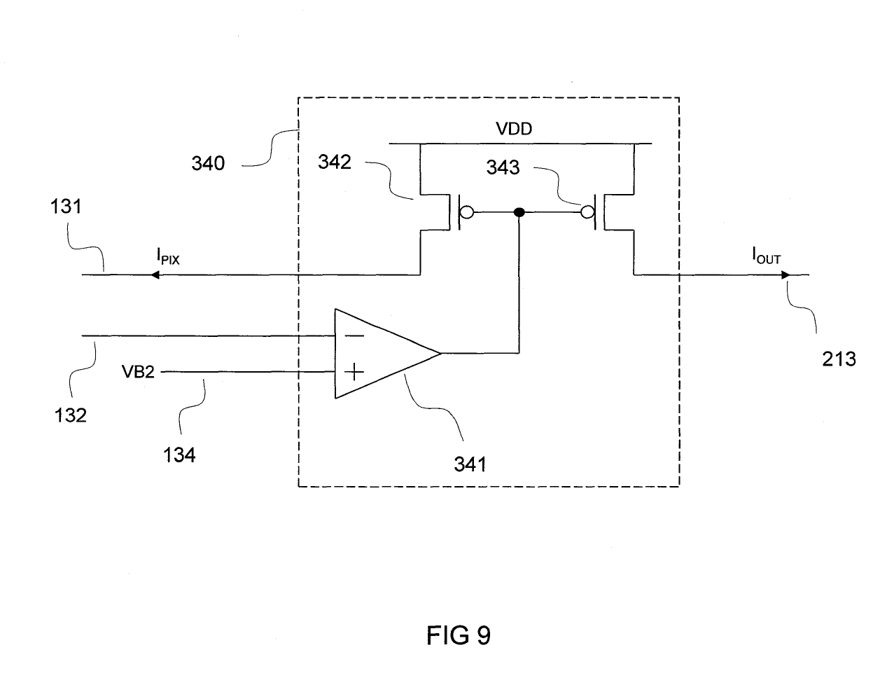

In a third embodiment of this invention, the current conveyor circuit 210 of the previous embodiments is replaced with an alternative form of current conveyor circuit that makes use of a current mirror formed by p-type transistors. This p-type current conveyor circuit 340 is shown in the schematic diagram of FIG. 9 and includes an operational amplifier 341 an input p-type transistor 342 and an output p-type transistor 343. The input and output transistors are well matched and form a current mirror. The source terminals of the p-type transistors 342,343 are connected to a high potential power supply (VDD), while their gate terminals are connected together and to the output of the operational amplifier 341. The drain terminal of the input transistor 342 is connected to the source drive addressing line 131 and the drain terminal of the output transistor 343 to the input of a current integrator circuit 220 of the type shown in FIG. 5, for example. The source sense addressing line 132 is connected to the negative input terminal of the operational amplifier such that, as previously described, the current conveyor circuit 340 acts to provide a constant bias voltage at the source terminal of the pixel amplifier transistor (e.g., 111 in FIG. 5; 301 in FIG. 8) whilst copying the signal current, I_{PIX}, to the output terminal 213 of the current conveyor circuit 340 as l_{OUT} to the current integrator input (which is then input to the input terminal of a current integrator circuit 220 of the type shown in FIG. 5, for example).

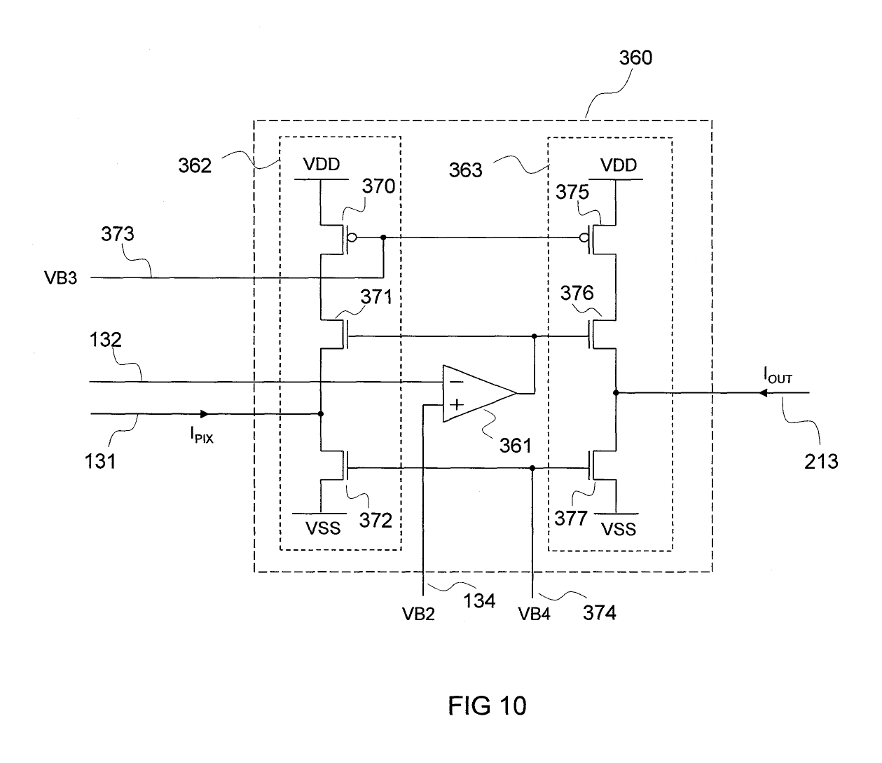

In a fourth embodiment of this invention, the current conveyor circuit of the previous embodiments is formed by a combination of n-type and p-type current mirrors. As shown in FIG. 10, this current conveyor circuit 360 includes an operational amplifier 361 and two branches, an input bias branch 362 and output bias branch 363. The input bias branch 362 includes a p-type transistor 370 and two n-type transistors 371, 372 connected in series between the high and low potential power supplies (VDD and VSS respectively). Similarly, the output bias branch 363 includes a p-type transistor 375 and two n-type transistors 376, 377 connected in series between the high and low potential power supplies (VDD and VSS respectively). The p-type transistor 370 of the input bias branch 362 and the p-type transistor 375 of the output bias branch 363 are well-matched and form a first p-type current mirror with a bias voltage (VB3) 373 supplied externally. The n-type transistor 372 of the input bias branch 362 and the n-type transistor 377 of the output bias branch 363 are well-matched and form a second n-type current mirror with a bias voltage (VB4) 374 supplied externally. The output terminal of the operational amplifier 361 is connected to the gate terminals of the n-type transistor 371 of the input bias branch 362 and the n-type transistor 376 of the output bias branch 363. The source drive addressing line 131 is connected to the node connecting the n-type transistors 371, 372, and the source sense addressing line 132 is connected to the negative input terminal of the operational amplifier 361. The output of the current conveyor circuit is connected to the node connecting the n-type transistors 376, 377. As in the preceding embodiments, the positive input terminal of the operational amplifier 361 is connected to the current conveyor reference voltage.

In operation, when sampling a pixel, the operational amplifier 361 will maintain the source sense addressing line 132—and hence the source terminal of the pixel amplifier transistor 111 (e.g., FIG. 5)—at a constant potential whilst copying the signal current, I_{PIX}, from the source drive addressing line 131 to the output terminal 213 of the current conveyor circuit 360. An advantage of the current conveyor circuit 360 is that the current is copied more accurately than the current conveyor circuits of the previous embodiments, due to a reduced effect of process mismatch.

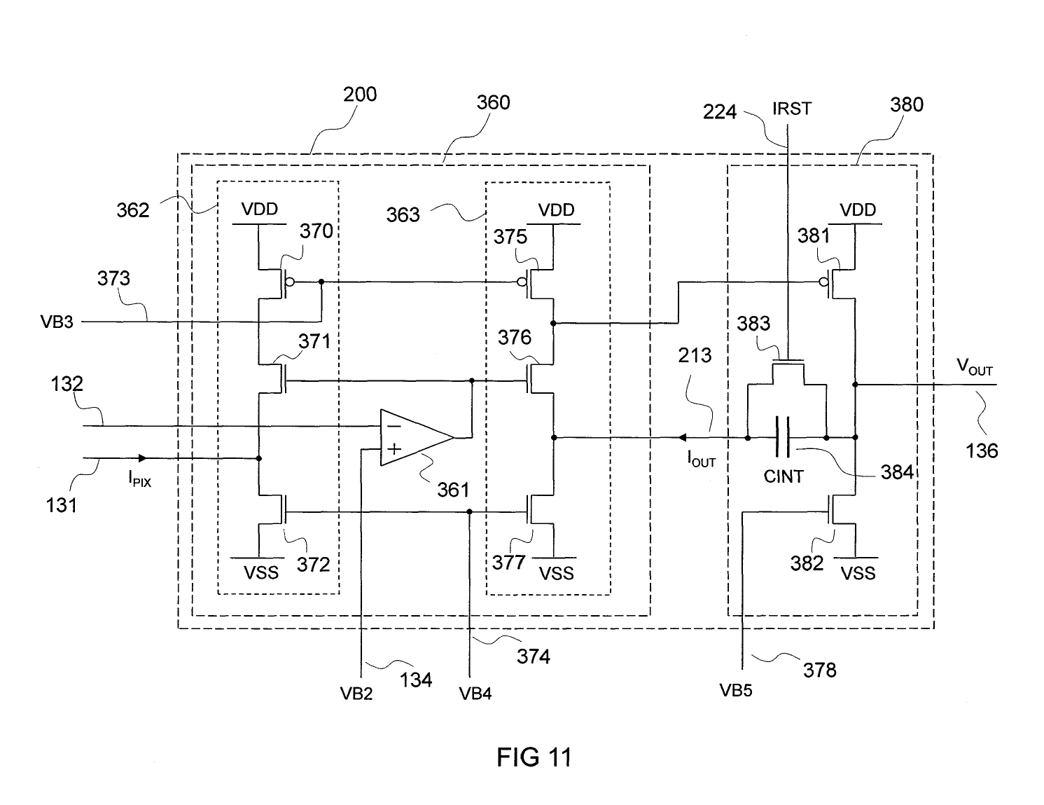

In a fifth embodiment of the invention, the current conveyor circuit 360 of the fourth embodiment is used in combination with an alternative current integrator circuit to reduce the size and power consumption of the read-out circuit. As shown in FIG. 11, the current integrator circuit 380 of this embodiment includes only four components: a p-type transistor 381; and n-type transistor 382; an integration capacitor (CINT) 384; and a reset switch which may be formed by a transistor 383. The p-type transistor 381 and n-type transistor 382 are connected in series between the high and low potential power supplies (VDD and VSS respectively) to form a common source amplifier. The gate terminal of the p-type transistor 381 is connected to the drain terminal of the p-type transistor 375, while the gate of the n-type transistor 382 is biased externally (VB5) 378. The integration capacitor 384 is connected as a feedback element between a node between the n-type transistors 376,377 of the output bias branch and a node between the p-type transistor 381 and the n-type transistor 382; and a voltage at the node between the p-type transistor 381 and the n-type transistor 382 represents an output voltage which is a function of the output signal current of the amplifying element of the selected pixel sensor circuit.

The operation cycle of the current conveyor circuit 360 with this current integrator circuit 380 is now briefly described. The first and second stages of the operation cycle, Periods 1 and 2, proceed as before and a voltage signal which is a function of the physical property to be measured is generated in the active pixel sensor circuit (e.g., 110 as shown in FIG. 5). In the third stage of operation, Period 3, the active pixel sensor circuit is selected and a signal current, I_{PIX}, begins to flow between the active pixel sensor circuit and the read-out circuit 200. The integrator reset signal (IRST) 224 is made high during this stage of operation turning on the switch transistor 383 of the current integrator circuit 380 and thus discharging the integration capacitor (CINT) 384 and forcing the output voltage (V_{OUT}) 136 to the same voltage as the current conveyor reference voltage (VB2) 134. In the fourth stage of operation, Period 4, the integrator reset signal (IRST) 224 is made low again thus turning off the switch transistor 383 and allowing integration of the signal current to begin. During the fourth stage of operation the signal current, I_{PIX}, is copied to the current conveyor output terminal 213, and hence the current integrator circuit 380 input, causing the integrator output voltage, V_{OUT}, to rise in proportion. Accordingly, at the end of the fourth stage of operation, the output voltage may be approximated by the same equation as for the previous embodiments:

$${V}_{OUT} = {V}_{B 2} + \frac{{I}_{OUT} Δ t}{{C}_{INT}}$$

where V_{B2} is the voltage of the current conveyor reference voltage (VB2) 134; Δt is the integrating period; and C_{INT} is the capacitance of the integrating capacitor (CINT) 384.

An advantage of this embodiment is that only one operational amplifier is required and the size and power consumption of the read-out circuit 200 may therefore be reduced. Further, the advantages associated with the current conveyor circuit 360 of the fourth embodiment are maintained and a measurement of high accuracy may be made.

So far, only the voltage drop created due to the parasitic resistance of the output signal line, or source drive addressing line 131, between the active pixel sensor circuit and the read-out circuit has been considered. However, the reference voltage address line (VB1) 115 also forms part for the conductive path for the signal current, I_{PIX}, and the parasitic resistance of this line 115 therefore causes a voltage drop between the control apparatus 240 and the active pixel sensor circuit 110 that is dependent on the signal current. The linearity of the sensor array system is therefore impaired. To further improve linearity, the voltage drop created by the parasitic resistance of the reference voltage address line (VB1) may also be eliminated.

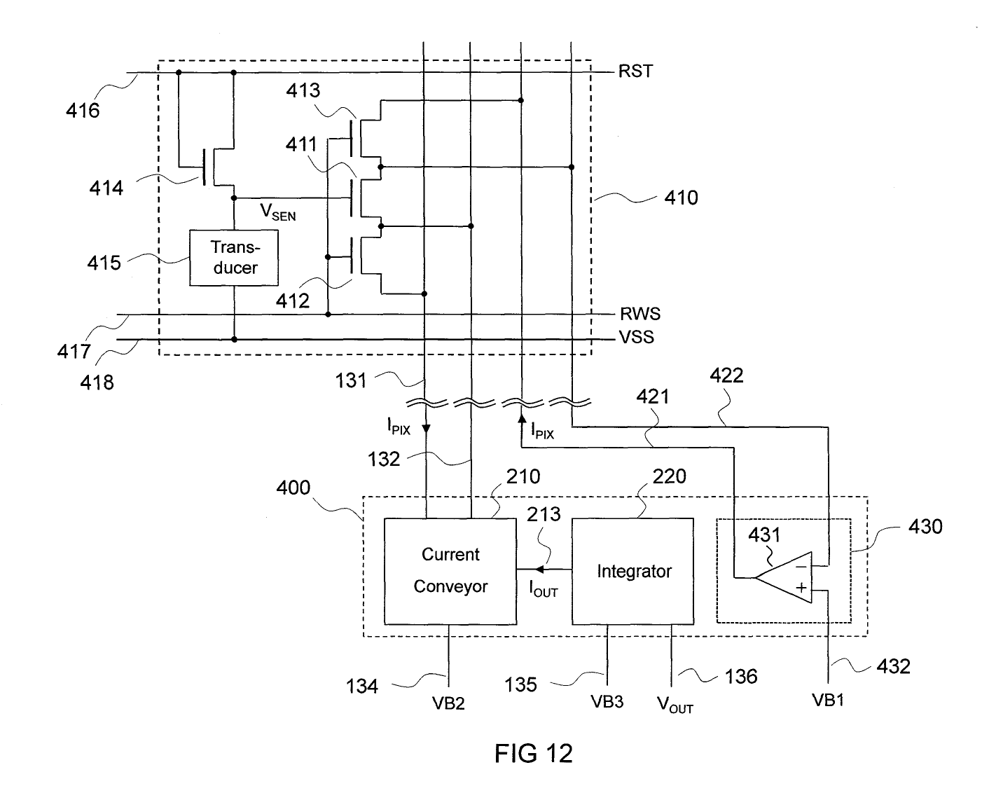

Accordingly, in a sixth embodiment of this invention (shown in FIG. 12), the sensor array system includes an active pixel sensor circuit and read-out circuit to eliminate voltage drop caused by the address line supplying a reference voltage to the drain of the pixel amplifier transistor. The active pixel sensor circuit 410 of this embodiment includes a transducer 415 and four transistors: an amplifier transistor 411; a source switch transistor 412; a drain switch transistor 413; and a reset transistor 414. The transducer 415 is connected both to the gate terminal of the amplifier transistor 411 and to a low potential power supply line (VSS) 418. A reset address line (RST) 416 is connected to the gate and drain terminals of the reset transistor 414, a row select line (RWS) 417 is connected to the gate terminals of both the source switch transistor 412 and the drain switch transistor 413. The source terminal of the source switch transistor 412 is connected to the read-out circuit 400 by means of a source drive addressing line 131 and the source terminal of the amplifier transistor 411 is connected to the read-out circuit 400 by means of a source sense addressing line 132. The drain terminal of the drain switch transistor 413 is connected to the read-out circuit 400 by means of a drain drive addressing line 421 and the drain terminal of the amplifier transistor 411 is connected to the read-out circuit 400 by means of the drain sense addressing line 422.

The read-out circuit 400 of this embodiment includes: a current conveyor circuit, such as the current conveyor circuit 210 of the first embodiment; a current integrator circuit, such as the current integrator circuit 220 of the first embodiment; and a biasing circuit 430. The biasing circuit 430 is used to maintain a constant bias voltage at the drain of the pixel amplifier transistor 411 and may, for example, include an operational amplifier 431 with a drain reference voltage (VB1) 432 applied to the positive input terminal of the operational amplifier 431 and the output terminal of the operational amplifier 431 connected to the negative input terminal via the drain drive addressing line 421, the pixel drain switch transistor 413 and the drain sense addressing line 422.

The operation cycle of the pixel circuit 410 and read-out circuit 400 is similar to the operation cycle as described in the first embodiment. However, during the third and fourth stages of operation (Periods 3 and 4) the drain switch transistor 413 is also turned on completing the feedback path of the biasing circuit 430 and configuring it as a unity gain amplifier. The biasing circuit 430 now acts to maintain the drain drive addressing line 421 at a voltage which causes the drain sense addressing line 422 to be equal to the drain reference voltage (VB1) 432. Further, the signal current, I_{PIX}, that is received by the current conveyor circuit 210 is now provided by the operational amplifier 431 of the biasing circuit 430. The signal current is sourced by the biasing circuit 430, flows down the drain drive addressing line 421, the channels of the drain switch transistor 413, amplifying transistor 411 and the source switch transistor 412 and finally down the source drive addressing line 131. However, since no current is drawn down the drain sense addressing line 422, the voltage at the drain of the pixel amplifier transistor 411 is maintained at the drain reference voltage (VB1) regardless of the signal current, I_{PIX}. The linearity of the sensor array system is therefore improved.

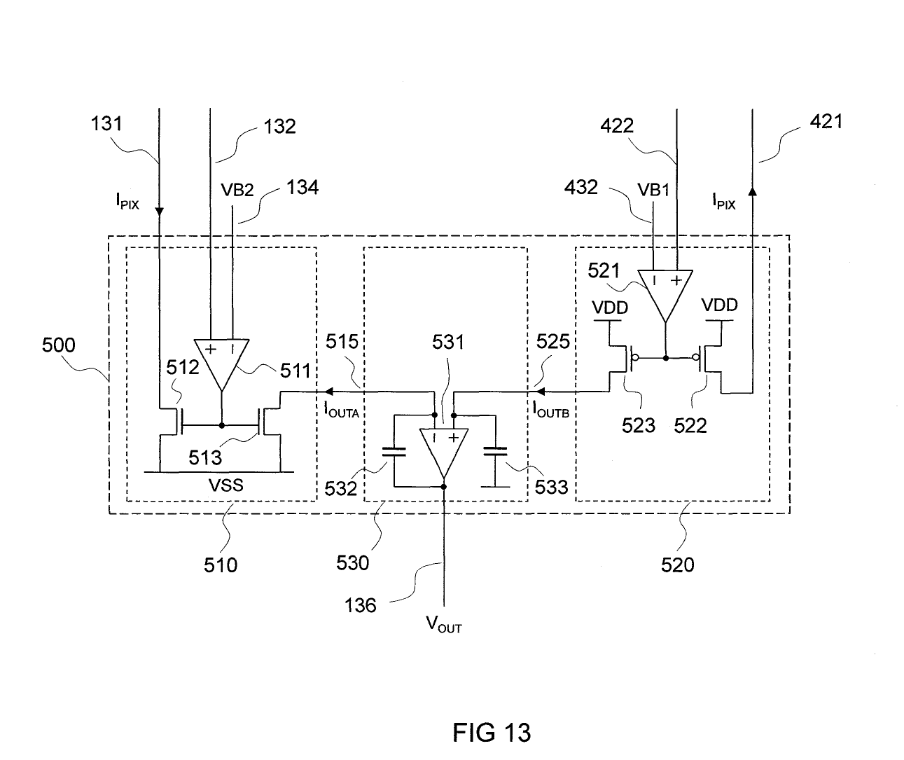

In accordance with a seventh embodiment of this invention the active pixel sensor circuit 410 of the sixth embodiment is used in combination with a differential read-out circuit 500 to improve the accuracy of the measurement. As shown in FIG. 13, the differential read-out circuit 500 includes a first current conveyor circuit 510, a second current conveyor circuit 520 and a differential current integrator circuit 530. The first current conveyor circuit 510 may be of a type capable of sinking current from the active pixel sensor circuit 410, for example similar to that described in the first embodiment, and include an operational amplifier 511 and an n-type current mirror including an n-type input transistor 512 and an n-type output transistor 513. The second current conveyor circuit 520 may also be of a type capable of sourcing current to the active pixel sensor circuit 410, for example similar to that described in the second embodiment, and include an operational amplifier 521 and a p-type current mirror including an input transistor 522 and an output transistor 523. The differential current integrator circuit 530 may be of a well-known type such as formed, for example, by: an operational amplifier 531; a first integrating capacitor 532 connected between the negative input and output terminals of the operational amplifier 531; and a second integrating capacitor 533 connected between the positive input terminal of the operational amplifier 531 and a low potential power supply.

The operation cycle of the active pixel sensor circuit 410 and the differential read-out circuit 500 is similar to the operation cycle as described in the seventh embodiment. However, during the third and fourth stages of operation when the source switch transistor 412 and drain switch transistor 413 are turned on, the second current conveyor circuit 520 acts to maintain the drain terminal of the pixel amplifier transistor 411 at the reference voltage (VB1) 432 whilst copying the signal current, I_{PIX}, from the drain drive addressing line 421 to the positive input terminal 525 of the current integrator circuit 530. The first current integrator circuit 510 acts as previously described to maintain the source terminal of the pixel amplifier transistor 411 at the current conveyor reference voltage (VB2) 134 whilst copying the signal current, I_{PIX}, from the source drive addressing line 131 to the negative input terminal 515 of the current integrator circuit 530. Since the first current conveyor circuit 510 acts as a current sink and the second current conveyor circuit 520 acts as a current source, the current I_{OUTA} flowing into the negative input terminal 515 of the current integrator circuit 530 is of equal magnitude but opposite sign to the current I_{OUTB} flowing into the positive input terminal 525. Electrical noise or interference will tend to act in common to both input signals and will therefore be rejected by the differential integrating circuit 530. As a result, the signal-to-noise ratio of the read-out circuit 500 of this embodiment is improved and a greater accuracy of measurement may be achieved.

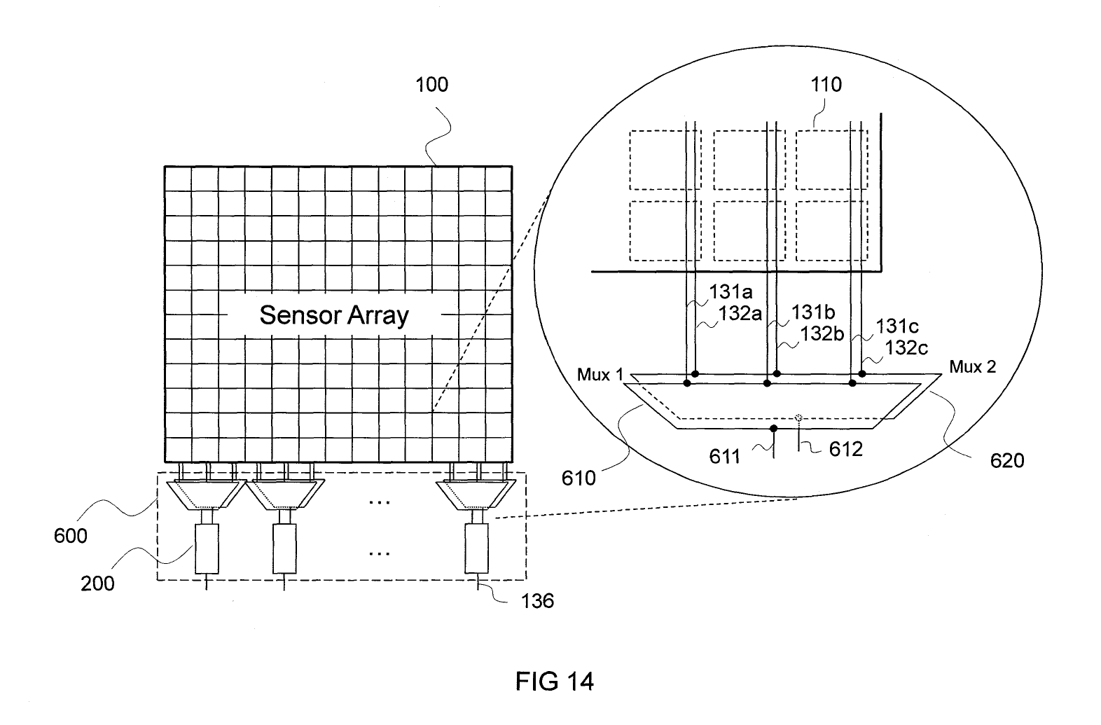

In accordance with an eighth embodiment of this invention, the read-out apparatus includes a plurality of multiplexers in order to reduce the total circuit size. FIG. 14 shows an example of the read-out apparatus 600 of this embodiment wherein a single read-out circuit, which may for example be of a type such as the read-out circuit 200 of the first embodiment, is connected to three columns of the sensor array 100 and shared via a pair of multiplexers 610, 620. The first multiplexer 610 is used to connect the source drive addressing lines 131a, 131b, 131c to the first input signal line 611 of the readout circuit 200. The second multiplexer 620 is used to connect the source sense addressing line lines 132a, 132b, 132c to the second input signal line 612 of the readout circuit 200. Both multiplexers are synchronised in such a way that in the fourth stage of the operation cycle, Period 4, the input signal lines represented by source drive signal 611 and source sense signal 612 of the readout circuit 200 are connected to each pair of addressing lines 131,132 associated with one particular column of the sensor array (for example 131a and 132a or 131b and 132b or 131c and 133c) in turn. The number of columns of the sensor array that are connected to a single read-out circuit is not limited to three and may be of any suitable number. Since the circuit area occupied by a multiplexer is considerably less than that of a read-out circuit, it is evident that the size of the read-out apparatus may be reduced by such an arrangement.

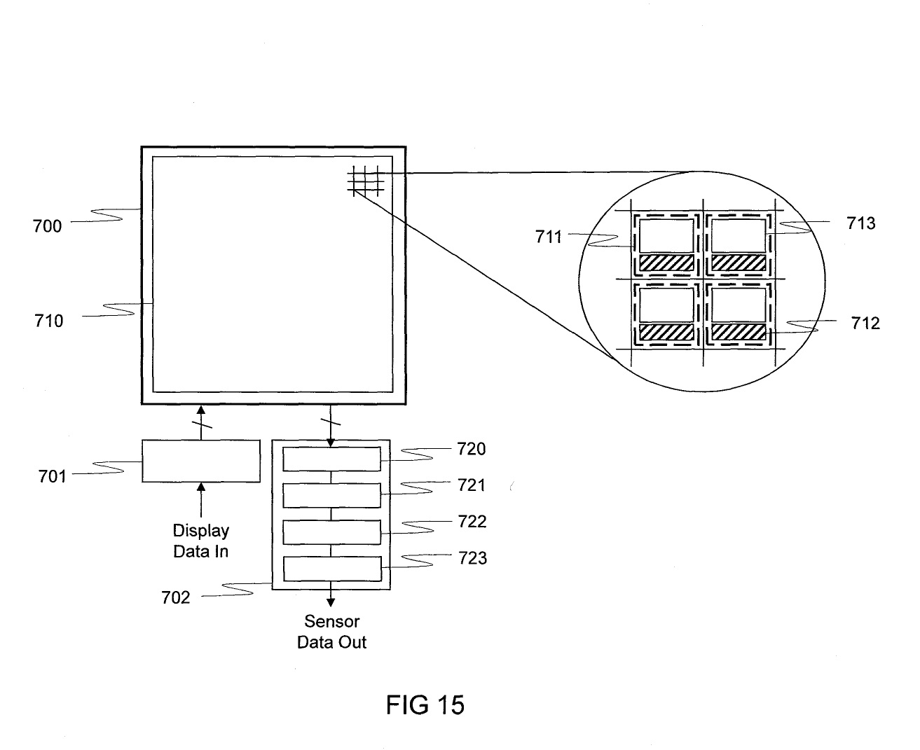

In accordance with a ninth embodiment of the present invention, a sensor array such as that described in any one of the preceding embodiments may find application, for example, in a liquid crystal display (LCD) integrated optical-type touch panel device. Such an application is well-known, for example as described in US 2010/0238135 (Brown et al.; published 23 Sep. 2010). Such a device, a block diagram of which is shown in FIG. 15, may comprise a display substrate 700, a display controller 701 and a touch panel controller 702. A pixel matrix 710 may be formed on the display substrate 700 and each pixel 711 may contain both image sensor active pixel sensor circuit elements 712 and display pixel circuit elements 713. The operation of the display pixel circuit elements 713 is controlled by a display controller 701 which may be separate from or combined with a sensor controller 702 which controls the operation of the active pixel sensor circuit elements 712. The sensor controller 702 includes a read-out apparatus 720 to sample the signals generated by the active pixel sensor circuit elements 712, a multiplexer 721, an analog-to-digital convertor 722 and a processing unit 723 to analyse the output signals.

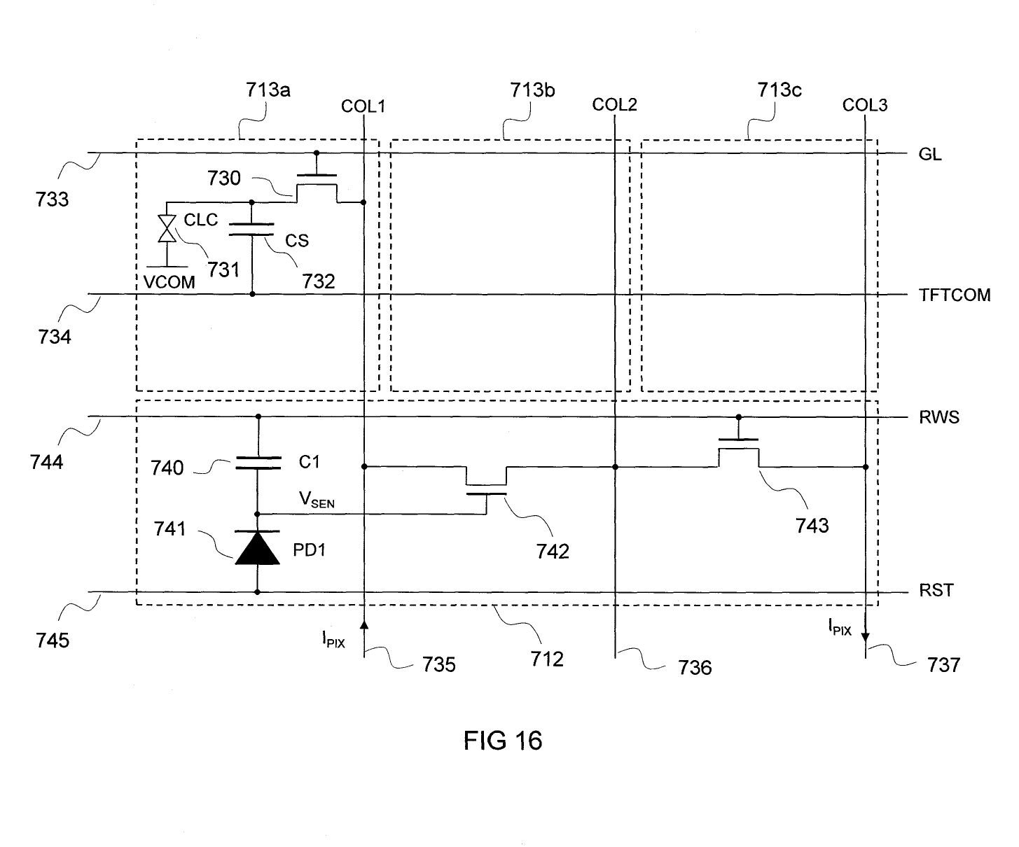

Alternatively, where the density of sensor pixels is not required to be as high as the density of display pixels, the active pixel sensor circuit elements 712 may be common to several pixels such that the total number of sensor pixels in the matrix is less than the total number of display pixels in the matrix. FIG. 16 shows a schematic diagram illustrating active pixel sensor circuit elements 712 which are integrated alongside three groups of pixel circuit elements 713 which form the three colour components of a full display pixel. The display circuit elements 713 may be of a construction well-known in the field of active matrix liquid crystal displays (AMLCDs) and comprise, for example, a switch transistor 730, a storage capacitor (CS) 732 and a liquid crystal element (CLC) 731. The active pixel sensor circuit elements 712 may be of a type described in any of the previously described embodiments for example, as shown in FIG. 16, the one-transistor active pixel sensor circuit described in the second embodiment. The active pixel sensor circuit elements may be distributed across the three groups of display circuit elements 713a, 713b and 713c. For example, the select capacitor (C1) 740 and photodiode 741 may be arranged adjacent to the first display circuit elements 713a, the pixel amplifier transistor 742 may be arranged adjacent to the second display circuit elements 713b and the pixel select transistor 743 may be arranged adjacent to the third display circuit elements 713c. A first column addressing line (COL1) 735 may be connected both to the source terminal of the switch transistor 730 of the first display circuit elements 713a and the drain terminal of the pixel amplifier transistor 712 of the active pixel sensor circuit elements. A second column addressing line (COL2) 735 may be connected to the source terminal of the switch transistor of the second display circuit elements 713b as well as the source terminal of the pixel amplifier transistor 742 and the drain terminal of the select transistor 743 of the active pixel sensor circuit elements. A third column addressing line (COL3) 735 may be connected both to the source terminal of the switch transistor of the third display circuit elements 713c and the source terminal of the pixel select transistor 743 of the active pixel sensor circuit elements.

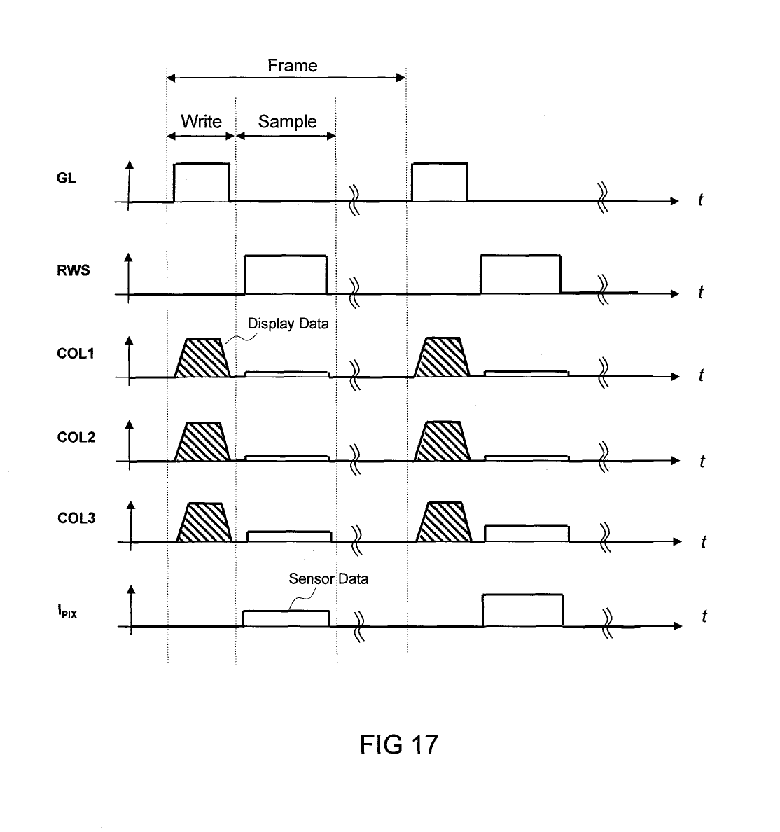

The operation cycle of the display circuit elements 712 is well-known and is not described further. The operation cycle of the active pixel sensor circuit elements is similar to that of the sensor pixel circuits previously described and includes four stages of operation. However, in order to use the column addressing lines 735, 736, 737 for the dual purposes of supplying data to the display pixel circuit elements and sampling the signal generated in the active pixel sensor circuit elements the display and sensor operations must be performed time sequentially. The operation of the display and sensor is now described with reference to the schematic diagram of FIG. 16 and the waveform diagram of FIG. 17. In one operating method, display data is written to the display circuit elements of one row of the matrix in a first write period and the signal generated by the active pixel sensor circuit elements of the same row of the matrix is then sampled in a second sample period. The write period and sample period together form one row period of the display operation. During the first write period, the display gate line (GL) 733 is made high and display data applied to the column addressing lines 735, 736, 737. The switch transistors 730 are therefore turned on and the liquid crystal element 731 and storage capacitor (CS) 732 of each display circuit elements 713 are charged to the voltage of the display data signals. At the end of the write period the gate line is made low turning off the switch transistors 730 and the display data is now stored. During the second sample period, the row select line (RWS) 744 is made high according to the third and fourth stages of the operation cycle of the active pixel sensor circuit elements. The first column addressing line (COL1) 735 is now supplied with a first reference voltage (VB1), the second column addressing line (COL2) 736 is used as the source sense addressing line, and the third addressing line (COL3) 737 is used as the source drive addressing line. As before, the read-out circuit (not shown) acts to maintain the voltage at the source terminal of the amplifier transistor 742 and samples the signal current from the third column addressing line 737. At the end of the sample period the row select line (RWS) 744 is made low. The next row of pixels may then be written and sampled in the next row period such that all pixels in the matrix are written and sampled during one frame period of the display operation.

The various transistors described herein may be any type of suitable transistor including, for example, MOSFETs, JFETs, bipolar, etc. While the present invention is described herein primarily in the context of MOSFETs in which each transistor includes a gate, drain and source, the transistors may be described more generally as will be appreciated in the context of each transistor including an input terminal, first output terminal and second output terminal. Thus, for example, the input terminal, first output terminal and second output terminal of a MOSFET may represent the gate, drain and source of the MOSFET, respectively. As another example, the input terminal, first output terminal and second output terminal of a bipolar transistor may represent the base, emitter and collector of the bipolar transistor, respectively. The invention, in the broadest sense, is not intended to be limited to the particular transistor types and polarity arrangements described herein.

The description above is intended to illustrate the integration of the active pixel sensor circuits and read-out circuits of this invention within an AMLCD to form, for example, an optical-type touch panel device. It is evident that any of the previously described active pixel sensor circuits may be integrated into the matrix of an AMLCD in a manner similar to that described above.

Although the invention has been shown and described with respect to a certain embodiment or embodiments, equivalent alterations and modifications may occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein exemplary embodiment or embodiments of the invention. In addition, while a particular feature of the invention may have been described above with respect to only one or more of several embodiments, such feature may be combined with one or more other features of the other embodiments, as may be desired and advantageous for any given or particular application.

### INDUSTRIAL APPLICABILITY

The invention overcomes disadvantages with sensor arrays having high address line resistances as occurs, for example, when the array is of a large physical size or when the process technology used in the fabrication of the array limits the conductivity of the material that can be used to create the address line. This invention finds application in different types of sensor arrays such as, but not limited to, image sensor arrays, chemical sensor arrays and touch panels including touch panels integrated within liquid crystal display (LCD) devices.

1. A sensor array, comprising:
a plurality of pixel sensor circuits;
a current-mode readout circuit to sample signals generated in each pixel sensor circuit; and
addressing circuitry to individually select each pixel sensor circuit,
wherein each pixel sensor circuit includes:
a transducer which converts a physical property to be measured to an electrical signal; and
an amplifying element coupled to the transducer and configured to output a signal current which varies as a function of the measured physical property; and
the current-mode readout circuit includes:
a sense signal line coupled to each of the amplifying elements in order to monitor the voltage presented across the amplifying element of the selected pixel sensor circuit;
a drive signal line coupled to an output of each of the amplifying elements in order to provide a constant bias voltage to the amplifying element of the selected pixel sensor circuit; and
a current conveyor circuit coupled to the sense signal line and drive signal line and configured to monitor the voltage presented across the amplifying element of the selected pixel sensor circuit using the sense signal line, provide the constant bias voltage to the amplifying element of the selected pixel sensor circuit using the drive signal line, and produce an output which is a function of the output signal current of the amplifying element of the selected pixel sensor circuit.

2. The sensor array according to claim 1, wherein each pixel sensor circuit includes an amplifier transistor as the amplifying element, the amplifier transistor having an input terminal coupled to an output of the transducer, a first output terminal coupled to a pixel reference voltage address line, and a second output terminal coupled to the sense signal line and the drive signal line.

3. The sensor array according to claim 2, wherein each pixel sensor circuit includes a select transistor having a first output terminal and a second output terminal through which the second output terminal of the amplifier transistor is coupled to the drive signal line, and the addressing circuitry includes a row select addressing line coupled to an input terminal of the select transistor for selecting the pixel sensor circuit.

4. The sensor array according to claim 2, wherein each pixel sensor circuit includes a reset transistor coupled to a reset address line included in the addressing circuitry for resetting an output of the transducer.

5. The sensor array according to claim 1, wherein the current conveyor circuit includes an operational amplifier, input transistor and output transistor arranged in a current mirror, the input transistor being coupled to the drive signal line to receive the output signal current of the amplifying element of the selected pixel sensor circuit, the output transistor being coupled to the output of the current conveyor circuit, input terminals of the operational amplifier being coupled to the sense signal line and a current conveyor reference voltage, respectively, and an output terminal of the operational amplifier being coupled to input terminals of the input transistor and output transistor.

6. The sensor array according to claim 5, wherein a first output terminal, second output terminal and the input terminal of the input transistor are coupled to the drive signal line, a low potential power supply line, and the output of the operational amplifier, respectively; a first output terminal, second output terminal and the input terminal of the output transistor are coupled to the output of the current conveyor circuit, the low potential power supply line, and the output of the operational amplifier, respectively; and a positive terminal and a negative terminal of the operational amplifier are coupled to the sense signal line and the current reference voltage, respectively.

7. The sensor array according to claim 5, wherein a first output terminal, second output terminal and the input terminal of the input transistor are coupled to the drive signal line, a high potential power supply line, and the output of the operational amplifier, respectively; a first output terminal, second output terminal and the input terminal of the output transistor are coupled to the output of the current conveyor circuit, the high potential power supply line, and the output of the operational amplifier, respectively; and a negative terminal and a positive terminal of the operational amplifier are coupled to the sense signal line and the current reference voltage, respectively.

8. The sensor array according to claim 1, the current conveyor circuit including an operational amplifier, and an input bias branch and an output bias branch,
wherein each of the input bias branch and the output bias branch includes an upper part and a lower part;
the upper part of the input bias branch and the upper part of the output bias branch are arranged to form a first current mirror, while the lower part of the input bias branch and the lower part of the output bias branch are arranged to form a second current mirror;
the drive signal line is connected to a node connecting the upper and lower parts of the input bias branch; the sense signal line is connected to a negative input terminal of the operational amplifier; a current conveyor reference voltage is connected to a positive input terminal of the operational amplifier; and an output of the current conveyor circuit is connected to a node connecting the upper and lower parts of the output bias branch.

9. The sensor array according to claim 8, wherein the current-mode readout circuit includes a current integrator circuit which integrates the output of the current conveyor circuit to produce an output voltage which is a function of the output signal current of the amplifying element of the selected pixel sensor circuit.

10. The sensor array according to claim 8, wherein the input bias branch includes a first p-type transistor and first and second n-type transistors connected in series between high and low potential power supplies; the output bias branch includes a second p-type transistor and third and fourth two n-type transistors connected in series between the high and low potential power supplies, the first and second p-type transistors are matched to form the first current mirror; one of the first and second n-type transistors of the input bias branch and one of the third and fourth n-type transistors of the output bias branch are matched to form the second current mirror; the output terminal of the operational amplifier is connected to gate terminals of the other of the first and second n-type transistors of the input bias branch and the other of the third and fourth n-type transistors of the output bias branch;
the node the drive signal line is connected to is a node connecting the first and second n-type transistors of the input bias branch; and the node the output of the current conveyor circuit is connected to is a node connecting the third and fourth n-type transistors of the output bias branch.

11. The sensor array according to claim 10, wherein the current-mode readout circuit includes a current integrator circuit for integrating the output of the current conveyor circuit, the current integrator circuit including a third p-type transistor and a fifth n-type transistor connected in series between the high and low power supplies, connected to form an amplifying stage therewith; an integration capacitor connected between a node between the third and fourth n-type transistors of the output bias branch and a node between the third p-type transistor and the fifth n-type transistor; and a voltage at the node between the third p-type transistor and the fifth n-type transistor represents an output voltage which is a function of the output signal current of the amplifying element of the selected pixel sensor circuit.

12. The sensor array according to claim 1, wherein:
each pixel sensor circuit includes an amplifier transistor as the amplifying element, the amplifier transistor having an input terminal coupled to an output of the transducer, a first output terminal, and a second output terminal which is coupled to the sense signal line and the drive signal line; and
the current-mode readout circuit further includes:
another sense signal line coupled to the first output terminal of each of the amplifier transistors in order to monitor the voltage presented across the amplifying element of the selected pixel sensor circuit; and
another drive signal line coupled to the first output terminal of each of the amplifier transistors in order to provide a constant bias voltage to the first output terminal of the amplifier transistor of the selected pixel sensor circuit.

13. The sensor array according to claim 12, wherein each pixel sensor circuit includes a first switch transistor having a first output terminal and a second output terminal through which the second output terminal of the amplifier transistor is coupled to the drive signal line, a second switch transistor having a first output terminal and a second output terminal through which the first output terminal of the amplifier transistor is coupled to the another drive signal line, and the addressing circuitry includes a row select addressing line coupled to a input terminal of the first and second switch transistors for selecting the pixel sensor circuit.

14. The sensor array according to claim 13, wherein the current-mode readout circuit includes a biasing circuit including an operational amplifier having a reference voltage connected to a positive input terminal thereof, and an output terminal of the operational amplifier being coupled to a negative input terminal thereof via the another drive signal line, the second switch transistor and the another sense signal line.

15. The sensor array according to claim 13, wherein the current conveyor circuit includes a first operational amplifier, first input transistor and first output transistor arranged in a first current mirror, the first input transistor being coupled to the drive signal line to receive the output signal current of the amplifier transistor of the selected pixel sensor circuit, and the first output transistor being coupled to a first input of a differential current integrator circuit; and
further comprising another current conveyor circuit including a second operational amplifier, second input transistor and second output transistor arranged in a second current mirror, the second input transistor being coupled to the another drive signal to source current to the amplifier transistor of the selected pixel sensor circuit, and the second output transistor being coupled to a second input of the differential current integrator circuit,
wherein one input terminal of the first and second operational amplifiers is coupled to the sense signal line and another sense signal line, respectively; and another input terminal of the first and second operational amplifiers is coupled to first and second current conveyor reference voltages, respectively.

16. A matrix-type sensor array, comprising:
a plurality of sensor arrays according to claim 1, wherein the plurality of pixel sensor circuits of each of the plurality of sensor arrays are arranged to form a corresponding column in a matrix of rows and columns.

17. The matrix-type sensor array according to claim 16, wherein multiple ones of the plurality of sensor arrays share a same current conveyor circuit selectively coupled to the corresponding sense signal line and drive signal line via a multiplexer.

18. A touch display, comprising a plurality of display pixels for providing a display, and a matrix-type sensor array of claim 16.

19. The touch display according to claim 18, wherein column addressing lines within the matrix-type sensor array are configured to serve a dual purpose of supplying display data to display pixels in the display and to sample the output of active pixel sensor circuits within the sensor array.

20. The sense array according to claim 1, wherein each pixel sensor circuit is common to multiple ones of the display pixels.

21. An array according to claim 1, incorporated in at least one of an image sensor array, chemical sensor array or touch panel.
